(19) United States
(12) Patent Application Publication
(10) Pub. No.: US 2026/0271319 A1
(43) Pub. Date: Sep. 10, 2026

(54) SEMICONDUCTOR DEVICE

(71) Applicant: SAMSUNG ELECTRONICS CO., LTD., Suwon-si (KR)

(72) Inventors: Jonghak Kim, Suwon-si (KR); Young Jun Byun, Suwon-si (KR); Heeseung Yoon, Suwon-si (KR); Seungtae Jung, Suwon-si (KR)

(73) Assignee: SAMSUNG ELECTRONICS CO., LTD., Suwon-si (KR)

(21) Appl. No.: 19/347,044

(22) Filed: Oct. 1, 2025

(30) Foreign Application Priority Data
Mar. 4, 2025 (KR) 10-2025-0027413

(51) Int. Cl. H10D 18/60; H10D 62/10; H10D 62/60; H10D 62/822; H10D 62/824; H10D 62/832; H10D 18/01

(52) U.S. Cl. CPC H10D 18/60; H10D 62/124; H10D 62/60; H10D 62/822; H10D 62/824; H10D 62/8325; H10D 18/01

(57) ABSTRACT

A semiconductor device includes a cathode electrode, a first semiconductor layer of a first conductivity type, a second semiconductor layer of a second conductivity type, a third semiconductor layer of the first conductivity type, and at least one fourth semiconductor layer of the second conductivity type that are sequentially stacked on the cathode electrode in a first direction, a gate electrode connected to the second semiconductor layer or the third semiconductor layer, an anode electrode on the at least one fourth semiconductor layer, and a first tunneling layer of the first conductivity type between the anode electrode and the at least one fourth semiconductor layer, where the second conductivity type is different from the first conductivity type and, in the first direction, a thickness of the first tunneling layer is less than a thickness of the at least one fourth semiconductor layer.

### CROSS-REFERENCE TO RELATED APPLICATION

This application is based on and claims priority to Korean Patent Application No. 10-2025-0027413, filed on Mar. 4, 2025, in the Korean Intellectual Property Office, the disclosure of which is incorporated by reference herein in its entirety.

### BACKGROUND

### 1. Field

The present disclosure relates to a semiconductor device.

### 2. Description of Related Art

A thyristor may have a four-layer PNPN structure, and may be turned on through the gate electrode, but once the thyristor enters a conducting state, it cannot be turned off except when the current is blocked externally or when the current in an AC circuit naturally commutates to zero. Due to these characteristics, thyristors may be used as devices capable of withstanding high voltages and large currents while providing high power conversion efficiency.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device that may provide an ohmic contact between a p-type semiconductor layer and an electrode of a semiconductor device using a semiconductor material having a high energy band gap.

Additional aspects will be set forth in part in the description which follows and, in part, will be apparent from the description, or may be learned by practice of the presented embodiments.

According to an aspect of an example embodiment, a semiconductor device may include a cathode electrode, a first semiconductor layer of a first conductivity type, a second semiconductor layer of a second conductivity type, a third semiconductor layer of the first conductivity type, and at least one fourth semiconductor layer of the second conductivity type that are sequentially stacked on the cathode electrode in a first direction, a gate electrode connected to the second semiconductor layer or the third semiconductor layer, an anode electrode on the at least one fourth semiconductor layer, and a first tunneling layer of the first conductivity type between the anode electrode and the at least one fourth semiconductor layer, where the second conductivity type is different from the first conductivity type and, in the first direction, a thickness of the first tunneling layer is less than a thickness of the at least one fourth semiconductor layer.

According to an aspect of an example embodiment, a semiconductor device may include a cathode electrode, a first semiconductor layer of a first conductivity type, a second semiconductor layer of a second conductivity type, a third semiconductor layer of the first conductivity type, and a fourth semiconductor layer of the second conductivity type that are sequentially stacked on the cathode electrode in a first direction, a gate electrode connected to the second semiconductor layer or the third semiconductor layer, an anode electrode on the fourth semiconductor layer, a first tunneling layer between the anode electrode and the fourth semiconductor layer, and a second tunneling layer between the first tunneling layer and the fourth semiconductor layer, where the second conductivity type is different from the first conductivity type and an energy band gap of the first tunneling layer is different from an energy band gap of the second tunneling layer.

According to an aspect of an example embodiment, a semiconductor device may include a cathode electrode, a first semiconductor layer of a first conductivity type, a second semiconductor layer of a second conductivity type, a third semiconductor layer of the first conductivity type, and a fourth semiconductor layer of the second conductivity type that are sequentially stacked on the cathode electrode, a gate electrode connected to the second semiconductor layer or the third semiconductor layer, an anode electrode on the fourth semiconductor layer, and a first tunneling layer between the anode electrode and the fourth semiconductor layer, where the first tunneling layer is of the second conductivity type, the second conductivity type is different from the first conductivity type, and an energy band gap of the first tunneling layer is less than an energy band gap of the fourth semiconductor layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view of a semiconductor device according to one or more embodiments;

FIG. 2 is an energy band diagram of a cross-section taken along line A-A’ of FIG. 1 according to one or more embodiments;

FIG. 3 is a cross-sectional view of a semiconductor device according to one or more embodiments;

FIG. 4 is a cross-sectional view of a semiconductor device according to one or more embodiments;

FIG. 5 is an energy band diagram of a cross-section taken along line B-B’ of FIG. 4 according to one or more embodiments;

FIG. 6 is a cross-sectional view of a semiconductor device according to one or more embodiments;

FIG. 7 is a cross-sectional view of a semiconductor device according to one or more embodiments;

FIG. 8 is an energy band diagram of a cross-section taken along line C-C’ of FIG. 7, according to one or more embodiments;

FIG. 9 is a cross-sectional view of a semiconductor device according to one or more embodiments; and

FIGS. 10, 11, 12 and 13 are cross-sectional views illustrating a manufacturing process of a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, the size and thickness of each component shown in the drawing are arbitrarily shown for convenience of explanation, so the present invention is not necessarily limited to what is shown. To clearly represent the various layers and areas in the drawing, the thickness is enlarged and shown. And in the drawing, for convenience of explanation, the thickness of some layers and areas is exaggerated.

A semiconductor device according to one or more embodiments may be a thyristor. For example, the semiconductor device may be a gate turn-off thyristor with improved turn-off characteristics. Thyristors are combinations of PNP and NPN transistors that may handle high voltage and high current through mutual current amplification effects. Gate turn-off thyristors may be turned on and off by a gate signal and have a fast switching speed. Accordingly, the semiconductor device according to one or more embodiments may be used as a power device, but embodiments are not limited thereto, and the use may be changed in various ways.

A gate turn-off thyristor has a structure similar to a conventional thyristor, but has the characteristic of being able to block current through the gate electrode. That is, the gate turn-off thyristor may not only be turned on by applying current to the gate, but may also be turned off by supplying reverse current to the gate. This allows the gate turn-off thyristor to provide efficient switching in high-voltage and high-current environments without a separate commutation circuit.

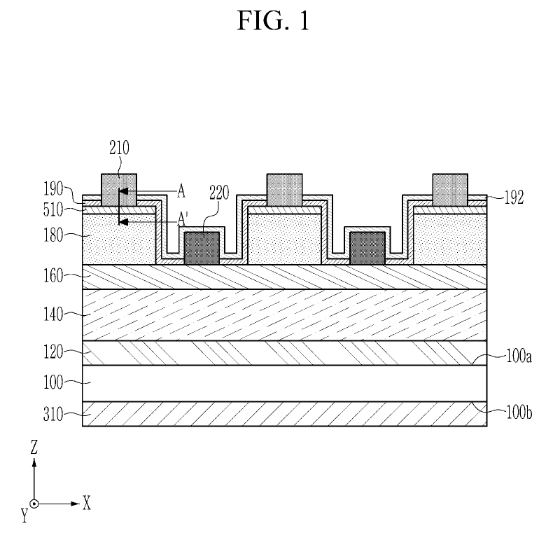

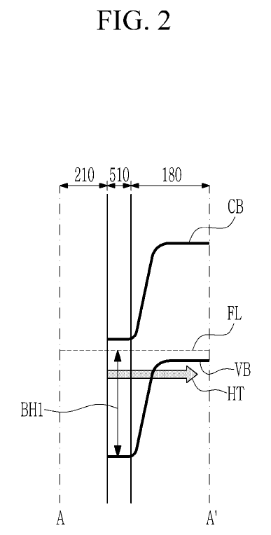

Hereinafter, a semiconductor device according to one or more embodiments will be described with reference to FIGS. 1 and 2.

FIG. 1 is a cross-sectional view of a semiconductor device according to one or more embodiments. FIG. 2 is an energy band diagram along line A-A’ of FIG. 1 according to one or more embodiments.

Referring to FIG. 1, a semiconductor device according to one or more embodiments may include a cathode electrode 310, a first semiconductor layer 120 of a first conductivity type, a second semiconductor layer 140 of a second conductivity type, a third semiconductor layer 160 of the first conductivity type, and a fourth semiconductor layer 180 of the second conductivity type sequentially stacked on the cathode electrode 310, a gate electrode 220 electrically connected to the third semiconductor layer 160, an anode electrode 210 positioned on the fourth semiconductor layer 180, and a tunneling layer 510 positioned between the anode electrode 210 and the fourth semiconductor layer 180.

In one or more embodiments, a substrate 100 may be positioned between the cathode electrode 310 and the first semiconductor layer 120. The substrate 100 may include a first surface 100a and a second surface 100b facing the first surface 100a. The first surface 100a of the substrate 100 may refer to the upper surface of the substrate 100, and the second surface 100b of the substrate 100 may refer to the lower surface of the substrate 100. In one or more embodiments, the first semiconductor layer 120, the second semiconductor layer 140, the third semiconductor layer 160, and the fourth semiconductor layer 180 may be positioned on the first surface 100a of the substrate 100. The cathode electrode 310 may be positioned on the second surface 100b of the substrate 100.

In FIG. 1, the substrate 100 is shown as being positioned between the cathode electrode 310 and the first semiconductor layer 120, but embodiments are not limited thereto. For example, the substrate 100 may be removed after being used in a manufacturing process of the semiconductor device and before forming the cathode electrode 310. For example, the substrate 100 may be omitted in the final structure of the semiconductor device. In this case, the cathode electrode 310 may contact the first semiconductor layer 120.

In one or more embodiments, the substrate 100 may be a semiconductor substrate including SiC. For example, the substrate 100 may be made of a 4H SiC substrate. In one or more embodiments, the substrate 100 may be made of a 3C SiC substrate, a 6H SiC substrate, etc. The substrate 100 may have the first conductivity type. The substrate 100 may be heavily doped with the first conductivity type. The first conductivity type may be n-type, but embodiments are not limited thereto. The doping concentration of the substrate 100 may be about 1*10¹⁷cm⁻³ or more and about 5*10²⁰cm⁻³ or less. The resistivity of the substrate 100 may be about 0.005Ωcm or more and about 0.035Ωcm or less. The thickness of the substrate 100 may be about 10 µm or more and about 700 µm or less. The material, doping type, doping concentration, resistivity, thickness, etc. of the substrate 100 are not limited thereto and may be changed in various ways.

In one or more embodiments, the first semiconductor layer 120, the second semiconductor layer 140, the third semiconductor layer 160, and the fourth semiconductor layer 180 may be sequentially stacked on the first surface 100a of the substrate 100. The lower surface of the first semiconductor layer 120 may contact the first surface 100a of the substrate 100. The lower surface of the second semiconductor layer 140 may contact the upper surface of the first semiconductor layer 120. The lower surface of the third semiconductor layer 160 may contact the upper surface of the second semiconductor layer 140. The lower surface of the fourth semiconductor layer 180 may contact the upper surface of the third semiconductor layer 160. However, embodiments are not limited thereto, and another layer may be additionally positioned between the substrate 100 and the first semiconductor layer 120, between the first semiconductor layer 120 and the second semiconductor layer 140, between the second semiconductor layer 140 and the third semiconductor layer 160, or between the third semiconductor layer 160 and the fourth semiconductor layer 180. The first semiconductor layer 120, the second semiconductor layer 140, the third semiconductor layer 160, and the fourth semiconductor layer 180 may be epitaxial layers formed from the substrate 100 using an epitaxial growth method.

The first semiconductor layer 120, the second semiconductor layer 140, the third semiconductor layer 160, and the fourth semiconductor layer 180 may include a semiconductor material doped with impurities. The first semiconductor layer 120, the second semiconductor layer 140, the third semiconductor layer 160, and the fourth semiconductor layer 180 may include the same semiconductor material. For example, the first semiconductor layer 120, the second semiconductor layer 140, the third semiconductor layer 160, and the fourth semiconductor layer 180 may be formed through an epitaxial growth method using the same semiconductor material as a seed. The first semiconductor layer 120, the second semiconductor layer 140, the third semiconductor layer 160, and the fourth semiconductor layer 180 may include a semiconductor material having a larger energy band gap than Si. In one or more embodiments, the first semiconductor layer 120, the second semiconductor layer 140, the third semiconductor layer 160, and the fourth semiconductor layer 180 may include SiC. For example, the first semiconductor layer 120, the second semiconductor layer 140, the third semiconductor layer 160, and the fourth semiconductor layer 180 may include 4H SiC. However, embodiments are not limited thereto, and the materials of the first semiconductor layer 120, the second semiconductor layer 140, the third semiconductor layer 160, and the fourth semiconductor layer 180 may be changed.

In one or more embodiments, the first semiconductor layer 120 may be of the first conductivity type. The first semiconductor layer 120 may be heavily doped with the first conductivity type. The first conductivity type may be n-type. The doping concentration of the first semiconductor layer 120 may be lower than the doping concentration of the substrate 100.

In one or more embodiments, the second semiconductor layer 140 may be of the second conductivity type. The second semiconductor layer 140 may be lightly doped with the second conductivity type. The second conductivity type may be different from the first conductivity type. The second semiconductor layer 140 may be p-type. The doping concentration of the second semiconductor layer 140 may be lower than the doping concentration of the fourth semiconductor layer 180. The doping concentration of the second semiconductor layer 140 may be about 1*1014cm-3 or more and about 1*1017cm-3 or less. The thickness of the second semiconductor layer 140 may be about 1 µm or more and about 13 µm or less. The doping concentration, thickness, etc. of the second semiconductor layer 140 are not limited thereto and may be changed in various ways.

In one or more embodiments, the third semiconductor layer 160 may be of the first conductivity type. The third semiconductor layer 160 may be lightly doped with the first conductivity type. The first conductivity type may be n-type. The doping concentration of the third semiconductor layer 160 may be lower than the doping concentration of the first semiconductor layer 120. The doping concentration of the third semiconductor layer 160 may be about 1*1014cm-3 or more and about 1*1019cm-3 or less. The thickness of the third semiconductor layer 160 may be about 0.3 µm or more and about 1.1 µm or less. The doping concentration, thickness, etc. of the third semiconductor layer 160 are not limited thereto and may be changed in various ways.

In one or more embodiments, the fourth semiconductor layer 180 may be of the second conductivity type. The fourth semiconductor layer 180 may be heavily doped with the second conductivity type. The second conductivity type may be p-type. The doping concentration of the fourth semiconductor layer 180 may be higher than the doping concentration of the second semiconductor layer 140. The doping concentration of the fourth semiconductor layer 180 may be about 1*10¹⁷cm⁻³ or more and about 5*10²⁰cm⁻³ or less. The doping concentration of the fourth semiconductor layer 180 is not limited to this and may be changed in various ways.

In one or more embodiments, the semiconductor device may include a plurality of fourth semiconductor layers 180 spaced apart in the first direction (e.g., the X direction) on the third semiconductor layer 160. The first direction (e.g., the X direction) may be a direction parallel to the upper surface of the third semiconductor layer 160.

In one or more embodiments, the gate electrode 220 may be positioned on the third semiconductor layer 160. The gate electrode 220 may be electrically connected to the third semiconductor layer 160. The gate electrode 220 may contact the third semiconductor layer 160. The lower surface of the gate electrode 220 may contact the upper surface of the third semiconductor layer 160.

In one or more embodiments, the gate electrode 220 may be positioned between the plurality of fourth semiconductor layers 180 spaced apart in the first direction (e.g., the X direction) on the third semiconductor layer 160. The gate electrode 220 may be spaced apart from the fourth semiconductor layer 180. The side surface of the gate electrode 220 may be spaced apart from the side surface of the fourth semiconductor layer 180.

In one or more embodiments, the semiconductor device may include a plurality of gate electrodes 220. The plurality of gate electrodes 220 may be arranged spaced apart from each other in the first direction (e.g., the X direction). The plurality of gate electrodes 220 may be alternately arranged with the plurality of fourth semiconductor layers 180 in the first direction (e.g., the X direction).

In one or more embodiments, the anode electrode 210 may be positioned on the fourth semiconductor layer 180. As the tunneling layer 510 is located between the anode electrode 210 and the fourth semiconductor layer 180, the anode electrode 210 may be located on the tunneling layer 510. The anode electrode 210 may be separated from the fourth semiconductor layer 180 by a tunneling layer 510.

In one or more embodiments, the semiconductor device may include a plurality of anode electrodes 210 each positioned on the plurality of fourth semiconductor layers 180 spaced apart in the first direction (e.g., the X direction). Each anode electrode 210 may be respectively positioned on each fourth semiconductor layer 180. The plurality of anode electrodes 210 may be arranged spaced apart from each other in the first direction (e.g., the X direction).

The anode electrode 210 and the gate electrode 220 may include a conductive material. For example, each of the anode electrode 210 and the gate electrode 220 may include a metal, an alloy, a conductive metal nitride, a metal silicide, a doped semiconductor material, a conductive metal oxide, a conductive metal oxynitride, or a combination thereof. Each of the anode electrode 210 and the gate electrode 220 may include titanium nitride TiN(TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but embodiments are not limited thereto. Each of the anode electrode 210 and the gate electrode 220 may be formed of a single layer or a plurality of layers.

In one or more embodiments, the anode electrode 210 and the gate electrode 220 may include different materials. However, embodiments are not limited thereto. For example, the anode electrode 210 and the gate electrode 220 may include the same material.

The semiconductor device according to one or more embodiments may further include a first protective layer 190 and a second protective layer 192. The first protective layer 190 may be positioned on the third semiconductor layer 160 and the fourth semiconductor layer 180. As the tunneling layer 510 is positioned between the anode electrode 210 and the fourth semiconductor layer 180, the first protective layer 190 may be positioned on the tunneling layer 510. The first protective layer 190 may cover the upper surface of the third semiconductor layer 160, the side surface of the fourth semiconductor layer 180, and the upper surface and side surface of the tunneling layer 510. The first protective layer 190 may cover a portion of the side surface of the gate electrode 220 on the third semiconductor layer 160. The first protective layer 190 may cover a portion of the side surface of the anode electrode 210 on the tunneling layer 510. The second protective layer 192 may be positioned on the first protective layer 190 and the gate electrode 220. The second protective layer 192 may cover the upper surface and side surface of the first protective layer 190. The second protective layer 192 may cover the upper surface and side surface of the gate electrode 220. The second protective layer 192 may cover the remaining portion of the side surface of the gate electrode 220 that is not covered by the first protective layer 190.

The first protective layer 190 and the second protective layer 192 may include an insulating material. For example, each of the first protective layer 190 and the second protective layer 192 may include, but is not limited to, silicon oxide, silicon phosphate, silicon nitride, silicon oxynitride, or a combination thereof.

In one or more embodiments, the cathode electrode 310 may be positioned on the second surface 100b of the substrate 100. The upper surface of the cathode electrode 310 may contact the second surface 100b of the substrate 100. However, embodiments are not limited thereto. For example, when the substrate 100 is removed in the final structure of the semiconductor device, the upper surface of the cathode electrode 310 may contact the lower surface of the first semiconductor layer 120.

The cathode electrode 310 may include a conductive material. For example, the cathode electrode 310 may include a metal, an alloy, a conductive metal nitride, a metal silicide, a doped semiconductor material, a conductive metal oxide, a conductive metal nitride, or a combination thereof. The cathode electrode 310 may include, but is not limited to, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. The cathode electrode 310 may be formed of a single layer or a plurality of layers.

The semiconductor device according to one or more embodiments may be a thyristor. For example, the semiconductor device may be a gate turn-off thyristor. For example, the semiconductor device may be a gate turn-off thyristor that combines a PNP transistor and an NPN transistor and may be turned on and off through a gate electrode. The second semiconductor layer 140, the third semiconductor layer 160, and the fourth semiconductor layer 180 may form a PNP transistor. The third semiconductor layer 160 may be a base region of a PNP transistor. The first semiconductor layer 120, the second semiconductor layer 140, and the third semiconductor layer 160 may form an NPN transistor. The second semiconductor layer 140 may be a base region of an NPN transistor. The gate electrode 220 may be electrically connected to the third semiconductor layer 160.

In order for an ohmic contact to be formed between the fourth semiconductor layer 180 doped with a p-type impurity in a semiconductor material having a larger energy band gap than Si and the anode electrode 210 including a metal material, the work function of the material of the anode electrode 210 may have to be greater than the work function of the material of the fourth semiconductor layer 180. However, metallic materials with a larger work function than semiconductor materials with a larger energy band gap than Si are limited, and the activation energy of p-type impurities doped into semiconductor materials with a larger energy band gap than Si may be large. Accordingly, it may be difficult to form an ohmic contact between the anode electrode 210 and the fourth semiconductor layer 180, and even if an ohmic contact is formed between the anode electrode 210 and the fourth semiconductor layer 180 through high-temperature heat treatment, the ohmic contact may be unstable and the characteristics of the device may deteriorate.

The semiconductor device according to one or more embodiments may include a tunneling layer 510 positioned between the anode electrode 210 and the fourth semiconductor layer 180. Accordingly, hole tunneling occurs between the anode electrode 210 and the fourth semiconductor layer 180, and current may flow. According to one or more embodiments, the semiconductor device may include the tunneling layer 510 so that an ohmic contact may be formed between the anode electrode 210 and the fourth semiconductor layer 180.

In one or more embodiments, the tunneling layer 510 may be of the first conductivity type. The tunneling layer 510 may have a different conductivity type from the fourth semiconductor layer 180 of the second conductivity type. In one or more embodiments, the first conductivity type may be n-type and the second conductivity type may be p-type. By positioning an n-type tunneling layer 510 between the anode electrode 210 and the p-type fourth semiconductor layer 180, the hole barrier height between the anode electrode 210 and the fourth semiconductor layer 180 may be increased. Accordingly, a hole tunneling phenomenon may occur and holes may be injected into the fourth semiconductor layer 180. The hole barrier height is the energy barrier that a hole must overcome. Hole tunneling is a phenomenon in which holes move through the quantum tunneling effect without directly crossing an energy barrier.

In one or more embodiments, the doping concentration of the tunneling layer 510 may be higher than the doping concentration of the third semiconductor layer 160. The doping concentration of the tunneling layer 510 may be higher than the doping concentration of the first semiconductor layer 120. In one or more embodiments, the doping concentration of the tunneling layer 510 may be greater than or equal to about 1*10¹⁹cm⁻³ and less than or equal to about 5*10²¹cm⁻³. The doping concentration of the tunneling layer 510 may be about 1*10²⁰cm⁻³ or more and about 1*10²¹cm⁻³ or less.

The thinner the tunneling layer 510, the more likely the tunneling phenomenon is to occur. In one or more embodiments, in the Z direction, the thickness of the tunneling layer 510 may be less than the thickness of the fourth semiconductor layer 180. The thickness of the tunneling layer 510 may be less than the thickness of the third semiconductor layer 160 in the Z direction. The thickness of the tunneling layer 510 may be less than the thickness of the second semiconductor layer 140 in the Z direction. The thickness of the tunneling layer 510 may be less than the thickness of the first semiconductor layer 120 in the Z direction.

In one or more embodiments, the thickness of the tunneling layer 510 may be less than or equal to about 20 nm in the Z direction. When the thickness of the tunneling layer 510 is about 20 nm or less in the Z direction, the hole tunneling phenomenon may occur easily. The occurrence of the tunneling phenomenon may indicate that the number of holes per unit volume injected into the fourth semiconductor layer 180 increases due to the tunneling effect. When the number of holes per unit volume injected into the fourth semiconductor layer 180 exceeds a specified value, an ohmic contact may be formed between the anode electrode 210 and the fourth semiconductor layer 180. In one or more embodiments, the anode electrode 210 and the fourth semiconductor layer 180 may be in ohmic contact as the thickness of the tunneling layer 510 is about 20 nm or less.

Referring to FIG. 2, the tunneling layer 510 may be positioned between the anode electrode 210 and the fourth semiconductor layer 180. In one or more embodiments, the tunneling layer 510 may contact the fourth semiconductor layer 180.

In one or more embodiments, as the conductivity type of the fourth semiconductor layer 180 is p-type, the Fermi level FL of the fourth semiconductor layer 180 may be adjacent to the valence band VB among the conduction band CB and the valence band VB. In one or more embodiments, as the conductivity type of the tunneling layer 510 is n-type, the Fermi level FL of the tunneling layer 510 may be adjacent to the conduction band CB among the conduction band CB and the valence band VB.

As the tunneling layer 510 contacts the fourth semiconductor layer 180, the energy band structures of the tunneling layer 510 and the fourth semiconductor layer 180 may change so that the Fermi levels FL of both become aligned. In one or more embodiments, as the tunneling layer 510 contacts the fourth semiconductor layer 180, the valence band VB of the fourth semiconductor layer 180 may rise, and the valence band VB of the tunneling layer 510 may fall. Accordingly, the hole barrier height BH1 that holes must overcome to be injected into the fourth semiconductor layer 180 may be increased. The hole barrier height BH1 may be the height from the valence band VB of the tunneling layer 510 that has been lowered to the Fermi level FL. Due to the increased hole barrier height BH1, holes may be injected into the fourth semiconductor layer 180 through the quantum tunneling phenomenon without directly crossing the energy barrier. The arrow HT shown in FIG. 2 indicates the direction in which holes tunnel and are injected into the fourth semiconductor layer 180.

When the tunneling layer 510 is thin, the hole tunneling phenomenon may occur. The thinner the tunneling layer 510, the more likely the hole tunneling phenomenon may occur. In one or more embodiments, the thickness of the tunneling layer 510 may be less than or equal to about 20 nm in the Z direction. When the thickness of the tunneling layer 510 is about 20 nm or less in the Z direction, an ohmic contact may be formed between the anode electrode 210 and the fourth semiconductor layer 180.

The semiconductor device according to one or more embodiments may include the tunneling layer 510 of the first conductivity type between the anode electrode 210 and the fourth semiconductor layer 180 of the second conductivity type. The second conductivity type may be different from the first conductivity type. The thickness of the tunneling layer 510 may be less than the thickness of the fourth semiconductor layer 180 in the Z direction. The thickness of the tunneling layer 510 may be about 20 nm or less in the Z direction. Accordingly, even if the fourth semiconductor layer 180 includes a p-type impurity and is made of a semiconductor material having a larger energy band gap than Si, and the work function of the material forming the anode electrode 210 is not larger than the work function of the material forming the fourth semiconductor layer 180, the anode electrode 210 and the fourth semiconductor layer 180 of the semiconductor device according to one or more embodiments may be in ohmic contact.

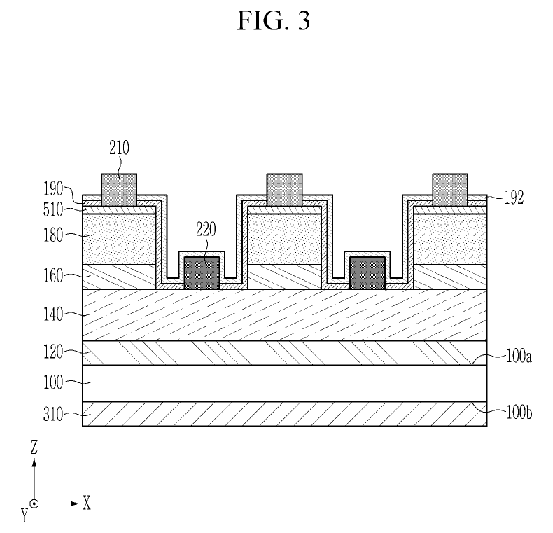

Hereinafter, a modified example of the semiconductor device according one or more embodiments will be described with reference to FIG. 3.

FIG. 3 is a cross-sectional view of a semiconductor device according to one or more embodiments. The embodiment illustrated in FIG. 3 may differ in some respects from the embodiment illustrated in FIG. 1 in that the gate electrode 220 contacts the second semiconductor layer 140. In FIG. 3, components that are identical to or have different features in some respects from those illustrated in FIG. 1 may be referenced by the same drawing reference numerals. Description of aspects that are the same as or similar to those described above may be omitted.

Referring to FIG. 3, the gate electrode 220 of the semiconductor device according to one or more embodiments may be electrically connected to the second semiconductor layer 140. The gate electrode 220 may contact the second semiconductor layer 140. The lower surface of the gate electrode 220 may contact the upper surface of the second semiconductor layer 140.

In one or more embodiments, the semiconductor device may include a plurality of third semiconductor layers 160 spaced apart in the first direction (e.g., the X direction). The gate electrode 220 may be positioned between the plurality of third semiconductor layers 160 spaced apart in the first direction (e.g., the X direction) on the second semiconductor layer 140. The plurality of fourth semiconductor layers 180 spaced apart in the first direction (e.g., the X direction) may be respectively positioned on the plurality of third semiconductor layers 160 spaced apart in the first direction (e.g., the X direction). The gate electrode 220 may be positioned between the plurality of fourth semiconductor layers 180 spaced apart in the first direction (e.g., the X direction) on the second semiconductor layer 140. The gate electrode 220 may be spaced apart from the third semiconductor layer 160 and the fourth semiconductor layer 180. The side of the gate electrode 220 may be spaced apart from the side surface of the third semiconductor layer 160 and the side surface of the fourth semiconductor layer 180.

In one or more embodiments, the semiconductor device may include the plurality of gate electrodes 220 spaced apart in the first direction (e.g., the X direction). The plurality of gate electrodes 220 may be alternately arranged with the plurality of third semiconductor layers 160 in the first direction (e.g., the X direction).

In one or more embodiments, the first protective layer 190 may cover the upper surface of the second semiconductor layer 140. The first protective layer 190 may cover the side surface of the third semiconductor layer 160 and the side surface of the fourth semiconductor layer 180. The first protective layer 190 may cover the upper surface and side surface of the tunneling layer 510.

The gate electrode 220 is electrically connected to the second semiconductor layer 140 by the lower surface of the gate electrode 220 contacting the upper surface of the second semiconductor layer 140, but embodiments are not limited thereto. For example, the gate electrode 220 may contact the side surface or lower surface of the second semiconductor layer 140. The electrical connection structure of the gate electrode 220 and the second semiconductor layer 140 may be changed in various ways.

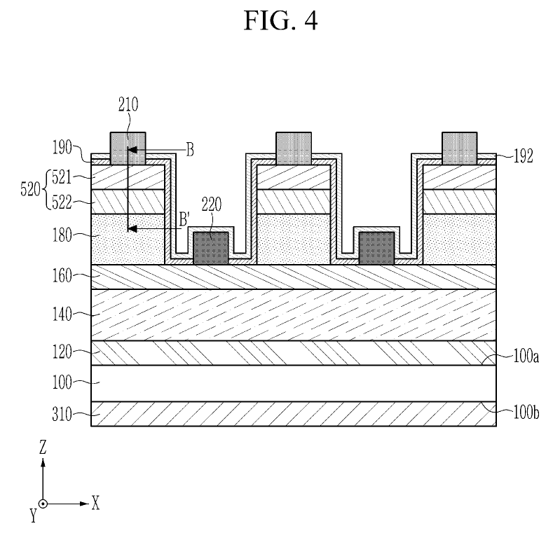

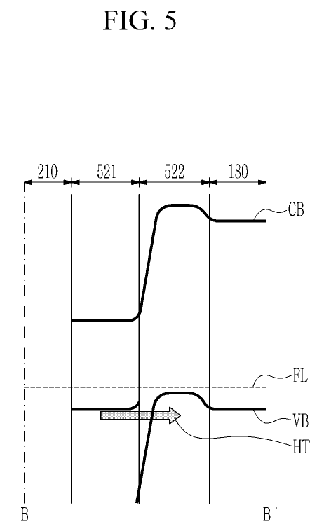

Hereinafter, a modified example of the semiconductor device will be described with reference to FIGS. 4 and 5.

FIG. 4 is a cross-sectional view of a semiconductor device according to one or more embodiments. FIG. 5 is an energy band diagram along line B-B’ of FIG. 4 according to one or more embodiments. The embodiment illustrated in FIG. 4 may be the same as the embodiment illustrated in FIG. 1 except that the tunneling layer. In the embodiment illustrated in FIG. 4, the same components as in the embodiment illustrated in FIG. 1 may be referenced with the same drawing reference numerals. Description of aspects that are the same as or similar to those described above may be omitted.

Referring to FIG. 4, a semiconductor device according to one or more embodiments may include a tunneling layer 520 between the anode electrode 210 and the fourth semiconductor layer 180 of the second conductivity type. The tunneling layer 520 may include a first tunneling layer 521 and a second tunneling layer 522. The second tunneling layer 522 may be positioned on the fourth semiconductor layer 180, and the first tunneling layer 521 may be positioned on the second tunneling layer 522. The first tunneling layer 521 may be positioned between the anode electrode 210 and the fourth semiconductor layer 180, and the second tunneling layer 522 may be positioned between the first tunneling layer 521 and the fourth semiconductor layer 180. The first tunneling layer 521 may be closer to the anode electrode 210 among the anode electrode 210 and the fourth semiconductor layer 180. The second tunneling layer 522 may be closer to the fourth semiconductor layer 180 among the anode electrode 210 and the fourth semiconductor layer 180. In one or more embodiments, the first tunneling layer 521 may contact the second tunneling layer 522. In one or more embodiments, the second tunneling layer 522 may contact the fourth semiconductor layer 180.

In one or more embodiments, the first tunneling layer 521 and the second tunneling layer 522 may be of the second conductivity type. The first tunneling layer 521 and the second tunneling layer 522 may have the same conductivity type as the fourth semiconductor layer 180. In one or more embodiments, the second conductivity type may be p-type. The first tunneling layer 521 and the second tunneling layer 522 may include a semiconductor material doped with p-type impurities.

In one or more embodiments, the first semiconductor layer 120, the second semiconductor layer 140, the third semiconductor layer 160, and the fourth semiconductor layer 180 may include a semiconductor material having a larger energy band gap than Si. For example, the first semiconductor layer 120, the second semiconductor layer 140, the third semiconductor layer 160, and the fourth semiconductor layer 180 may include SiC.

In one or more embodiments, the first tunneling layer 521 may include a semiconductor material having a smaller energy band gap than the fourth semiconductor layer 180. The first tunneling layer 521 may include a semiconductor material that contains the same elements as the fourth semiconductor layer 180, but has a smaller energy band gap than the material of the fourth semiconductor layer 180.

In one or more embodiments, the fourth semiconductor layer 180 and the first tunneling layer 521 may include Si and C, and the first tunneling layer 521 may further include an element other than Si and C. For example, the first tunneling layer 521 may further include Ge in addition to Si and C. For example, the fourth semiconductor layer 180 may include SiC, and the first tunneling layer 521 may include SiₓGe_{y}C_{1-x-y} where x>0 and y>0. In one or more embodiments, the content of the element added other than the same elements as those in the fourth semiconductor layer 180 among the elements of the first tunneling layer 521 may be 50 at% or less. For example, the first tunneling layer 521 may include SiₓGe_{y}C_{1-x-y}, where 0 < y ≤ 0.5. The content of an element added other than the same element as the fourth semiconductor layer 180 among the elements of the first tunneling layer 521 may be 50 at% or less, and may be equal to or greater than the content (at%) of Si. For example, the first tunneling layer 521 may include SiₓGe_{y}C_{1-x-y}, where 0 < y ≤ 0.5 and x ≤ y. In one or more embodiments, the atomic ratio of the same elements as those in the fourth semiconductor layer 180 among the elements of the first tunneling layer 521 may be 1:1, but embodiments are not limited thereto. For example, the first tunneling layer 521 may include SiₓGe_{y}C_{1-x-y}, and x:(1-x-y) may be 1:1, but embodiments are not limited thereto.

However, Ge is only an example, and the first tunneling layer 521 may contain the same elements as the fourth semiconductor layer 180 but may also contain another element so that the energy band gap of the first tunneling layer 521 is smaller than that of the fourth semiconductor layer 180.

FIG. 4 represents a case where the first tunneling layer 521 includes the same element as the fourth semiconductor layer 180 and further includes a different element, but embodiments are not limited thereto. For example, the fourth semiconductor layer 180 and the first tunneling layer 521 may include Si and C, and the Si content (at%) of the first tunneling layer 521 may be higher than the Si content (at%) of the fourth semiconductor layer 180. For example, the fourth semiconductor layer 180 may include SiₘC₁₋ₘ, the first tunneling layer 521 may include SiₙC₁₋ₙ, where n > m.

In one or more embodiments, the doping concentration of the first tunneling layer 521 including Si and C may be about 1*10¹⁸ cm⁻³ or more and about 1*10²⁰ cm⁻³ or less.

In one or more embodiments, the second tunneling layer 522 may include a semiconductor material having a larger energy band gap than the first tunneling layer 521. The second tunneling layer 522 may include the same elements as the first semiconductor layer 120 and may include a semiconductor material having a larger energy band gap than the material of the first tunneling layer 521. In one or more embodiments, the second tunneling layer 522 may include the same material as the fourth semiconductor layer 180. For example, the first tunneling layer 521 may include SiₓGe_{y}C_{1-x-y}, and the second tunneling layer 522 and the fourth semiconductor layer 180 may include SiC.

In one or more embodiments, the doping concentration of the second tunneling layer 522 may be higher than the doping concentration of the first tunneling layer 521. The doping concentration of the second tunneling layer 522 may be higher than the doping concentration of the fourth semiconductor layer 180. In one or more embodiments, the doping concentration of the second tunneling layer 522 including Si and C may be greater than or equal to about 1*10¹⁹cm⁻³ and less than or equal to about 5*10²¹cm⁻³. The doping concentration of the second tunneling layer 522 may be about 1*10²⁰cm⁻³ or more and about 1*10²¹cm⁻³ or less.

The above-described embodiments include a case where the first semiconductor layer 120, the second semiconductor layer 140, the third semiconductor layer 160, and the fourth semiconductor layer 180 include SiC, but embodiments are not limited thereto. For example, the first semiconductor layer 120, the second semiconductor layer 140, the third semiconductor layer 160, and the fourth semiconductor layer 180 may include GaN.

In one or more embodiments, the first tunneling layer 521 may include a semiconductor material having a smaller energy band gap than the first semiconductor layer 120. The first tunneling layer 521 may include a semiconductor material that contains the same elements as the first semiconductor layer 120, but has a smaller energy band gap than the material of the first semiconductor layer 120.

In one or more embodiments, the fourth semiconductor layer 180 and the first tunneling layer 521 may include Ga and N, and the first tunneling layer 521 may further include an element other than Ga and N. For example, the first tunneling layer 521 may further include In in addition to Ga and N. For example, the fourth semiconductor layer 180 may include GaN, and the first tunneling layer 521 may include InₚGa₁₋ₚN, where p>0. In one or more embodiments, the content of the element added other than the same elements as those in the fourth semiconductor layer 180 among the elements of the first tunneling layer 521 may be 50 at% or less. For example, the first tunneling layer 521 may include InₚGa₁₋ₚN, where 0 < p ≤ 0.5. The content of an element added other than the same element as the fourth semiconductor layer 180 among the elements of the first tunneling layer 521 may be 50 at% or less, and may be equal to or less than the content (at%) of Ga. For example, the first tunneling layer 521 may include InₚGa₁₋ₚN, where 0 < p ≤ 0.5. In one or more embodiments, the atomic ratio of the same elements as those in the fourth semiconductor layer 180 among the elements of the first tunneling layer 521 may be 1:1, but embodiments are not limited thereto.

However, In is only an example, and the first tunneling layer 521 may contain the same elements as the fourth semiconductor layer 180 but may also contain another element so that the energy band gap of the first tunneling layer 521 is smaller than that of the fourth semiconductor layer 180.

In one or more embodiments, the doping concentration of the first tunneling layer 521 including Ga and N may be about 1*10¹⁷ cm⁻³ or more and about 1*10²⁰ cm⁻³ or less.

In one or more embodiments, the second tunneling layer 522 may include a semiconductor material having a larger energy band gap than the first tunneling layer 521. The second tunneling layer 522 may include the same elements as the fourth semiconductor layer 180 and may include a semiconductor material having a larger energy band gap than the material of the first tunneling layer 521. In one or more embodiments, the second tunneling layer 522 may include the same material as the fourth semiconductor layer 180. For example, the first tunneling layer 521 may include InₚGa₁₋ₚN, and the second tunneling layer 522 and the fourth semiconductor layer 180 may include GaN.

In one or more embodiments, the doping concentration of the second tunneling layer 522 may be higher than the doping concentration of the first tunneling layer 521. The doping concentration of the second tunneling layer 522 may be higher than the doping concentration of the fourth semiconductor layer 180. In one or more embodiments, the doping concentration of the second tunneling layer 522 including Ga and N may be greater than or equal to about 1*10¹⁸ cm⁻³ and less than or equal to about 1*10²⁰ cm⁻³.

Referring to FIG. 5, a tunneling layer 520 may be positioned between the anode electrode 210 and the fourth semiconductor layer 180. The tunneling layer 520 may include the first tunneling layer 521 and the second tunneling layer 522. The first tunneling layer 521 may be positioned between the anode electrode 210 and the fourth semiconductor layer 180, and the second tunneling layer 522 may be positioned between the first tunneling layer 521 and the fourth semiconductor layer 180. In one or more embodiments, the first tunneling layer 521 may contact the second tunneling layer 522. In one or more embodiments, the second tunneling layer 522 may contact the fourth semiconductor layer 180.

In one or more embodiments, as the conductivity types of the fourth semiconductor layer 180, the first tunneling layer 521, and the second tunneling layer 522 are p-type, the Fermi level FL of each of the fourth semiconductor layer 180, the first tunneling layer 521, and the second tunneling layer 522 may be adjacent to the valence band VB among the conduction band CB and the valence band VB.

In one or more embodiments, the energy band gap of the first tunneling layer 521 may be smaller than the energy band gap of the second tunneling layer 522. The energy band gap refers to the energy difference between the conduction band CB and the valence band VB, which may correspond to the height difference between the conduction band CB level and the valence band VB level. As the first tunneling layer 521 contacts the second tunneling layer 522, the energy band structures of the first tunneling layer 521 and the second tunneling layer 522 may change so that the Fermi levels FL of both become aligned. In one or more embodiments, as the first tunneling layer 521 contacts the second tunneling layer 522, a notch may be formed between the first tunneling layer 521 and the second tunneling layer 522 in which the valence band VB is sharply and discontinuously bent. Holes may accumulate in the notch formed in the valence band VB. As the hole density increases, the tunneling probability of the holes may increase. In one or more embodiments, the notch is formed in the valence band VB at the contact surface of the first tunneling layer 521 including a material having a relatively small energy band gap and the second tunneling layer 522 including a material having a relatively large energy band gap, and holes accumulated in the notch may be injected into the second tunneling layer 522 through a quantum tunneling phenomenon. The arrow HT shown in FIG. 5 indicates the direction in which holes tunnel and are injected into the second tunneling layer 522.

In one or more embodiments, the doping concentration of the second tunneling layer 522 may be higher than the doping concentration of the first tunneling layer 521. In one or more embodiments, the first tunneling layer 521 and the second tunneling layer 522 may include a semiconductor material doped with a p-type impurity. In this case, as the doping concentration of the second tunneling layer 522 is higher than the doping concentration of the first tunneling layer 521, the valence band VB of the second tunneling layer 522 may be closer to the Fermi level FL than the valence band of the first tunneling layer 521. In this case, the depth of the notch formed between the first tunneling layer 521 and the second tunneling layer 522 may be deeper. As the notch deepens, the density of holes accumulated in the notch increases, and the hole tunneling phenomenon may occur more easily.

In one or more embodiments, the material of the second tunneling layer 522 and the material of the fourth semiconductor layer 180 may have the same energy band gap. The second tunneling layer 522 may include the same semiconductor material as the fourth semiconductor layer 180.

In one or more embodiments, the second tunneling layer 522 includes the same semiconductor material as the fourth semiconductor layer 180, but the doping concentration of the second tunneling layer 522 may be higher than the doping concentration of the fourth semiconductor layer 180. In one or more embodiments, the second tunneling layer 522 and the fourth semiconductor layer 180 may include a semiconductor material doped with a p-type impurity. In this case, as the doping concentration of the second tunneling layer 522 is higher than the doping concentration of the fourth semiconductor layer 180, the valence band VB of the second tunneling layer 522 may be closer to the Fermi level FL than the valence band of the fourth semiconductor layer 180. For example, the valence band VB of the second tunneling layer 522 may have a higher energy level than the valence band of the fourth semiconductor layer 180. Accordingly, holes may move from the second tunneling layer 522 to the fourth semiconductor layer 180.

The semiconductor device according to one or more embodiments includes the first tunneling layer 521 of the second conductivity type positioned between the anode electrode 210 and the fourth semiconductor layer 180 of the second conductivity type, and the first tunneling layer 521 may include a semiconductor material having a smaller energy band gap than that of the fourth semiconductor layer 180. As the first tunneling layer 521 has a smaller energy band gap than the fourth semiconductor layer 180, the work function of the first tunneling layer 521 is smaller than that of the fourth semiconductor layer 180, and the activation energy of the p-type impurity in the first tunneling layer 521 may be smaller than that of the fourth semiconductor layer 180. Accordingly, when the first tunneling layer 521 is positioned between the anode electrode 210 and the fourth semiconductor layer 180, it is easier for the anode electrode 210 and the fourth semiconductor layer 180 to make ohmic contact than when the anode electrode 210 is directly connected to the fourth semiconductor layer 180.

The semiconductor device according to one or more embodiments includes the second tunneling layer 522 of the second conductivity type between the first tunneling layer 521 and the fourth semiconductor layer 180, and the second tunneling layer 522 may include a semiconductor material having a larger energy band gap than the first tunneling layer 521. In one or more embodiments, the doping concentration of the second tunneling layer 522 may be higher than the doping concentration of the first tunneling layer 521. As the first tunneling layer 521 contacts the second tunneling layer 522, the valence band VB notch may be formed at the contact surface of the first tunneling layer 521 and the second tunneling layer 522, and as holes accumulate in the notch and the hole density increases, a hole tunneling phenomenon may occur easily. The hole may move from the first tunneling layer 521 to the second tunneling layer 522 through the hole tunneling phenomenon. In one or more embodiments, the doping concentration of the second tunneling layer 522 may be higher than the doping concentration of the fourth semiconductor layer 180. Holes may move from the second tunneling layer 522 to the fourth semiconductor layer 180 due to the energy level difference of the valence band VB depending on the doping concentration. Accordingly, even if the fourth semiconductor layer 180 includes a p-type impurity and is made of a semiconductor material having a larger energy band gap than Si, and the work function of the material forming the anode electrode 210 is not larger than the work function of the material forming the fourth semiconductor layer 180, the anode electrode 210 and the fourth semiconductor layer 180 of the semiconductor device according to one or more embodiments may be in ohmic contact.

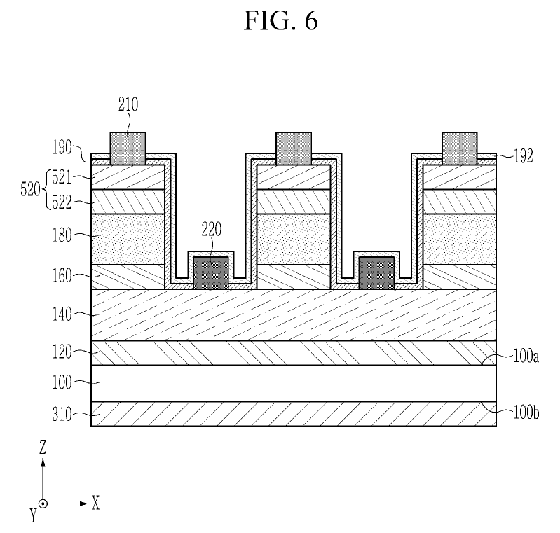

Hereinafter, a modified example of the semiconductor device will be described with reference to FIG. 6.

FIG. 6 is a cross-sectional view of a semiconductor device according to one or more embodiments. The embodiment illustrated in FIG. 6 may differ in some respects from the embodiment illustrated in FIG. 4 in that the gate electrode 220 contacts the second semiconductor layer 140. In the embodiment illustrated in FIG. 6, components that are identical to or have different features in some respects from those illustrated in FIG. 4 may be referenced by the same drawing reference numerals. Description of aspects that are the same as or similar to those described above may be omitted.

Referring to FIG. 6, the gate electrode 220 of the semiconductor device according to one or more embodiments may be electrically connected to the second semiconductor layer 140. The gate electrode 220 may contact the second semiconductor layer 140. The lower surface of the gate electrode 220 may contact` the upper surface of the second semiconductor layer 140.

In one or more embodiments, the semiconductor device may include a plurality of third semiconductor layers 160 spaced apart in the first direction (e.g., the X direction). The gate electrode 220 may be positioned between the plurality of third semiconductor layers 160 spaced apart in the first direction (e.g., the X direction) on the second semiconductor layer 140. The plurality of fourth semiconductor layers 180 spaced apart in the first direction (e.g., the X direction) may be respectively positioned on the plurality of third semiconductor layers 160 spaced apart in the first direction (e.g., the X direction). The gate electrode 220 may be positioned between the plurality of fourth semiconductor layers 180 spaced apart in the first direction (e.g., the X direction) on the second semiconductor layer 140. The gate electrode 220 may be spaced apart from the third semiconductor layer 160 and the fourth semiconductor layer 180. The side surface of the gate electrode 220 may be spaced apart from the side surface of the third semiconductor layer 160 and the side surface of the fourth semiconductor layer 180.

In one or more embodiments, the semiconductor device may include the plurality of gate electrodes 220 spaced apart in the first direction (e.g., the X direction). The plurality of gate electrodes 220 may be alternately arranged with the plurality of third semiconductor layers 160 in the first direction (e.g., the X direction).

In one or more embodiments, the first protective layer 190 may cover the upper surface of the second semiconductor layer 140. The first protective layer 190 may cover the side surface of the third semiconductor layer 160 and the side surface of the fourth semiconductor layer 180. The first protective layer 190 may cover the upper surface and side surfaces of the tunneling layer 520. The first protective layer 190 may cover the upper surface and side surface of the first tunneling layer 521 and the side surface of the second tunneling layer 522.

The gate electrode 220 may be electrically connected to the second semiconductor layer 140 by the lower surface of the gate electrode 220 contacting the upper surface of the second semiconductor layer 140, but embodiments are not limited thereto. For example, the gate electrode 220 may contact the side surface or lower surface of the second semiconductor layer 140. The electrical connection structure of the gate electrode 220 and the second semiconductor layer 140 may be changed in various ways.

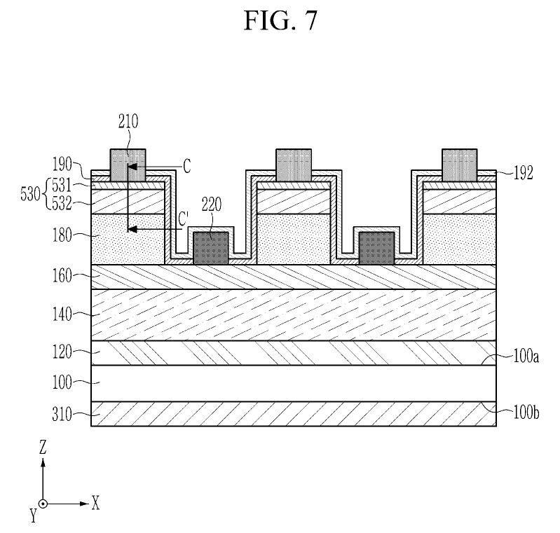

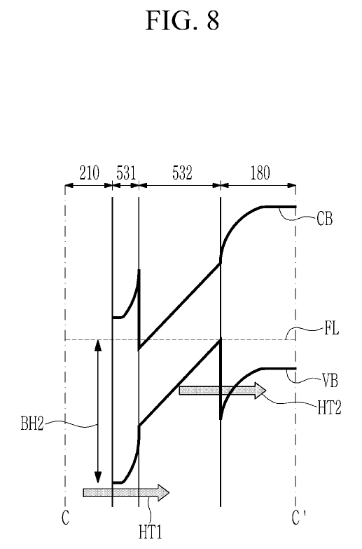

Hereinafter, a modified example of the semiconductor device will be described with reference to FIGS. 7 and 8.

FIG. 7 is a cross-sectional view of a semiconductor device according to one or more embodiments. FIG. 8 is an energy band diagram along line B-B’ of FIG. 7 according to one or more embodiments. The embodiment illustrated in FIG. 7 may be the same as the embodiment illustrated in FIG. 1 except that the tunneling layer. In the embodiment illustrated in FIG. 7, the same components as in the embodiment illustrated in FIG. 1 may be referenced with the same drawing reference numerals. Description of aspects that are the same as or similar to those described above may be omitted.

Referring to FIG. 7, a semiconductor device according to one or more embodiments may include a tunneling layer 530 between the anode electrode 210 and the fourth semiconductor layer 180 of the second conductivity type. The tunneling layer 530 may include the first tunneling layer 531 and the second tunneling layer 532. The second tunneling layer 532 may be positioned on the fourth semiconductor layer 180, and the first tunneling layer 531 may be positioned on the second tunneling layer 532. The first tunneling layer 531 may be positioned between the anode electrode 210 and the fourth semiconductor layer 180, and the second tunneling layer 532 may be positioned between the first tunneling layer 521 and the fourth semiconductor layer 180. The first tunneling layer 531 may be closer to the anode electrode 210 among the anode electrode 210 and the fourth semiconductor layer 180. The second tunneling layer 532 may be closer to the fourth semiconductor layer 180 among the anode electrode 210 and the fourth semiconductor layer 180. In one or more embodiments, the first tunneling layer 531 may contact the second tunneling layer 532. In one or more embodiments, the second tunneling layer 532 may contact the fourth semiconductor layer 180.

In one or more embodiments, the first tunneling layer 521 may be of the first conductivity type and the second tunneling layer 522 may be of the second conductivity type. The first tunneling layer 521 and the second tunneling layer 522 may have different conductivity types. In one or more embodiments, the first conductivity type may be n-type and the second conductivity type may be p-type. The first tunneling layer 521 may include a semiconductor material doped with an n-type impurity, and the second tunneling layer 522 may include a semiconductor material doped with a p-type impurity.

In one or more embodiments, the first tunneling layer 531 of n-type is positioned between the anode electrode 210 and the second tunneling layer 532 of p-type, so that the hole barrier height between the anode electrode 210 and the second tunneling layer 532 may be increased. Accordingly, a hole tunneling phenomenon may occur and holes may be injected into the second tunneling layer 532.

In one or more embodiments, the doping concentration of the first tunneling layer 531 may be higher than the doping concentration of the third semiconductor layer 160. The doping concentration of the first tunneling layer 531 may be higher than the doping concentration of the first semiconductor layer 120. In one or more embodiments, the doping concentration of the first tunneling layer 531 may be greater than or equal to about 1*10¹⁹cm⁻³ and less than or equal to about 5*10²¹cm⁻³. The doping concentration of the first tunneling layer 531 may be about 1*10²⁰cm⁻³ or more and about 1*10²¹cm⁻³ or less.

The thinner the first tunneling layer 531, the more likely the tunneling phenomenon is to occur. In one or more embodiments, the thickness of the first tunneling layer 531 may be thinner than the thickness of the fourth semiconductor layer 180 in the Z direction. The thickness of the first tunneling layer 531 may be less than the thickness of the third semiconductor layer 160 in the Z direction. The thickness of the first tunneling layer 531 may be less than the thickness of the second semiconductor layer 140 in the Z direction. The thickness of the first tunneling layer 531 may be less than the thickness of the first semiconductor layer 120 in the Z direction. In one or more embodiments, the thickness of the first tunneling layer 531 may be about 20 nm or less in the Z direction.

In one or more embodiments, the first semiconductor layer 120, the second semiconductor layer 140, the third semiconductor layer 160, and the fourth semiconductor layer 180 may include a semiconductor material having a larger energy band gap than Si. For example, the first semiconductor layer 120, the second semiconductor layer 140, the third semiconductor layer 160, and the fourth semiconductor layer 180 may include SiC.

In one or more embodiments, the second tunneling layer 532 may include a semiconductor material having a smaller energy band gap than the fourth semiconductor layer 180. The second tunneling layer 532 may include a semiconductor material that contains the same elements as the fourth semiconductor layer 180, but has a smaller energy band gap than the material of the fourth semiconductor layer 180.

In one or more embodiments, the fourth semiconductor layer 180 and the second tunneling layer 532 may include Si and C, and the second tunneling layer 532 may further include an element other than Si and C. For example, the second tunneling layer 532 may further include Ge in addition to Si and C. For example, the fourth semiconductor layer 180 may include SiC, and the second tunneling layer 532 may include SiₓGe_{y}C_{1-x-y} where x>0 and y>0. In one or more embodiments, the content of the element added other than the same elements as those in the fourth semiconductor layer 180 among the elements of the second tunneling layer 532 may be 50 at% or less. For example, the second tunneling layer 532 may include SiₓGe_{y}C_{1-x-y}, where 0 < y ≤ 0.5. The content of an element added other than the same element as the fourth semiconductor layer 180 among the elements of the second tunneling layer 532 may be 50 at% or less, and may be equal to or greater than the content (at%) of Si. For example, the second tunneling layer 532 may include SiₓGe_{y}C_{1-x-y}, where 0 < y ≤ 0.5 and x ≤ y. In one or more embodiments, the atomic ratio of the same elements as those in the first semiconductor layer 120 among the elements of the second tunneling layer 532 may be 1:1, but embodiments are not limited thereto. For example, the second tunneling layer 532 may include SiₓGe_{y}C_{1-x-y}, and x:(1-x-y) may be 1:1, but embodiments are not limited thereto.

However, Ge is only an example, and the second tunneling layer 532 may contain the same elements as the fourth semiconductor layer 180 but may also contain another element so that the energy band gap is smaller than that of the fourth semiconductor layer 180.

The above-described embodiment is a case where the second tunneling layer 532 includes the same element as the fourth semiconductor layer 180 and further includes a different element, but embodiments are not limited thereto. For example, the fourth semiconductor layer 180 and the second tunneling layer 532 may include Si and C, and the Si content (at%) of the second tunneling layer 532 may be higher than the Si content (at%) of the fourth semiconductor layer 180. For example, the fourth semiconductor layer 180 may include SiₘC₁₋ₘ, the second tunneling layer 532 may include SiₙC₁₋ₙ, where n > m.

In one or more embodiments, the doping concentration of the second tunneling layer 532 including Si and C may be greater than or equal to about 1*10¹⁸ cm⁻³ and less than or equal to about 1*10²⁰ cm⁻³.

In one or more embodiments, the first tunneling layer 531 may include a semiconductor material having a larger energy band gap than the second tunneling layer 532. The first tunneling layer 531 may include the same elements as the fourth semiconductor layer 180 and may include a semiconductor material having a larger energy band gap than the material of the second tunneling layer 532. In one or more embodiments, the first tunneling layer 531 may include the same material as the fourth semiconductor layer 180. For example, the second tunneling layer 532 may include SiₓGe_{y}C_{1-x-y}, and the first tunneling layer 531 and the fourth semiconductor layer 180 may include SiC.

The above-described embodiments include a case where the first semiconductor layer 120, the second semiconductor layer 140, the third semiconductor layer 160, and the fourth semiconductor layer 180 include SiC, but embodiments are not limited thereto. For example, the first semiconductor layer 120, the second semiconductor layer 140, the third semiconductor layer 160, and the fourth semiconductor layer 180 may include GaN.

In one or more embodiments, the second tunneling layer 532 may include a semiconductor material having a smaller energy band gap than the fourth semiconductor layer 180. The second tunneling layer 532 may include a semiconductor material that contains the same elements as the fourth semiconductor layer 180, but has a smaller energy band gap than the material of the fourth semiconductor layer 180.

In one or more embodiments, the fourth semiconductor layer 180 and the second tunneling layer 532 may include Ga and N, and the second tunneling layer 532 may further include an element other than Ga and N. For example, the second tunneling layer 532 may further include In in addition to Ga and N. For example, the fourth semiconductor layer 180 may include GaN, and the second tunneling layer 532 may include InₚGa₁₋ₚN, where p>0. In one or more embodiments, the content of the element added other than the same elements as those in the fourth semiconductor layer 180 among the elements of the second tunneling layer 532 may be 50 at% or less. For example, the second tunneling layer 532 may include InₚGa₁₋ₚN, where 0 < p ≤ 0.5. The content of the element added other than the same elements as those in the fourth semiconductor layer 180 among the elements of the second tunneling layer 532 may be 50 at% or less, and may be equal to or less than the content (at%) of Ga. For example, the second tunneling layer 532 may include InₚGa₁₋ₚN, where 0 < p ≤ 0.5. In one or more embodiments, the atomic ratio of the same elements as those in the fourth semiconductor layer 180 among the elements of the second tunneling layer 532 may be 1:1, but embodiments are not limited thereto.

However, In is only an example, and the second tunneling layer 532 may contain the same elements as the fourth semiconductor layer 180 but may also contain another element so that the energy band gap is smaller than that of the fourth semiconductor layer 180.

In one or more embodiments, the doping concentration of the second tunneling layer 532 including Ga and N may be greater than or equal to about 1*10¹⁷ cm⁻³ and less than or equal to about 1*10²⁰ cm⁻³.

In one or more embodiments, the first tunneling layer 531 may include a semiconductor material having a larger energy band gap than the second tunneling layer 532. The energy band gap of the second tunneling layer 532 may be smaller than the energy band gap of the first tunneling layer 531. The first tunneling layer 531 may include the same elements as the fourth semiconductor layer 180 and may include a semiconductor material having a larger energy band gap than the material of the second tunneling layer 532. In one or more embodiments, the first tunneling layer 531 may include the same material as the fourth semiconductor layer 180. For example, the second tunneling layer 532 may include InₚGa₁₋ₚN, and the first tunneling layer 531 and the fourth semiconductor layer 180 may include GaN.

Referring to FIG. 8, the tunneling layer 530 may be positioned between the anode electrode 210 and the fourth semiconductor layer 180. The tunneling layer 530 may include the first tunneling layer 531 and the second tunneling layer 532. The first tunneling layer 531 may be positioned between the anode electrode 210 and the fourth semiconductor layer 180, and the second tunneling layer 532 may be positioned between the first tunneling layer 531 and the fourth semiconductor layer 180. In one or more embodiments, the first tunneling layer 531 may contact the second tunneling layer 532. In one or more embodiments, the second tunneling layer 532 may contact the fourth semiconductor layer 180.

In one or more embodiments, as the conductivity types of the second tunneling layer 532 and the fourth semiconductor layer 180 are p-type, the Fermi level FL of the second tunneling layer 532 and the fourth semiconductor layer 180 may be adjacent to the valence band VB among the conduction band CB and the valence band VB. In one or more embodiments, as the conductivity type of the first tunneling layer 531 is n-type, the Fermi level FL of the first tunneling layer 531 may be adjacent to the conduction band CB among the conduction band CB and the valence band VB.

As the first tunneling layer 531 contacts the second tunneling layer 532, the energy band structures of the first tunneling layer 531 and the second tunneling layer 532 may change so that the Fermi levels FL of both become aligned. In one or more embodiments, as the first tunneling layer 531 contacts the second tunneling layer 532, the valence band VB of the second tunneling layer 532 may rise, and the valence band VB of the first tunneling layer 531 may fall. Accordingly, the hole barrier height BH2 that holes must overcome to be injected into the second tunneling layer 532 may be increased. Here, the hole barrier height BH2 may be the height from the valence band VB of the lowered first tunneling layer 531 to the Fermi level FL. Due to the increased hole barrier height BH2, holes may be injected into the second tunneling layer 532 through the quantum tunneling phenomenon without directly crossing the energy barrier. The first arrow HT1 shown in FIG. 8 indicates the direction in which holes tunnel and are injected into the second tunneling layer 532.

In one or more embodiments, the energy band gap of the second tunneling layer 532 may be smaller than the energy band gap of the first tunneling layer 531. At the contact surface between the first tunneling layer 531 and the second tunneling layer 532, the energy level of the valence band VB of the first tunneling layer 531 which has a relatively large energy band gap and is n-type may be lower, and the energy level of the valence band VB of the second tunneling layer 532 which has a relatively small energy band gap and is p-type may be higher. Accordingly, the hole barrier height BH2 that holes must overcome to be injected into the second tunneling layer 532 may be increased.

When the first tunneling layer 531 is thin, a hole tunneling phenomenon may occur. The thinner the first tunneling layer 531, the more likely the hole tunneling phenomenon may occur. In one or more embodiments, the thickness of the first tunneling layer 531 may be about 20 nm or less in the Z direction. When the thickness of the first tunneling layer 531 is about 20 nm or less in the Z direction, the hole tunneling phenomenon may occur easily. In one or more embodiments, when the thickness of the first tunneling layer 531 is about 20 nm or less in the Z direction, an ohmic contact may be formed between the anode electrode 210 and the second tunneling layer 532.

In one or more embodiments, the energy band gap of the second tunneling layer 532 may be smaller than the energy band gap of the fourth semiconductor layer 180. As the second tunneling layer 532 contacts the fourth semiconductor layer 180, the energy band structures of the second tunneling layer 532 and the fourth semiconductor layer 180 may change so that the Fermi levels FL of both become aligned. In one or more embodiments, as the second tunneling layer 532 contacts the fourth semiconductor layer 180, a notch in which the valence band VB is sharply and discontinuously bent may be formed between the second tunneling layer 532 and the fourth semiconductor layer 180. Holes may accumulate in the notch formed in the valence band VB. As the hole density increases, the tunneling probability of the holes may increase. In one or more embodiments, the notch is formed in the valence band VB at the contact surface between the second tunneling layer 532 including a material having a relatively small energy band gap and the fourth semiconductor layer 180 including a material having a relatively large energy band gap, and holes accumulated in the notch may be injected into the fourth semiconductor layer 180 through a quantum tunneling phenomenon. The second arrow HT2 shown in FIG. 8 indicates the direction in which holes tunnel and are injected into the fourth semiconductor layer 180.

The semiconductor device according to one or more embodiments may include the first tunneling layer 531 of the first conductivity type positioned between the anode electrode 210 and the fourth semiconductor layer 180 of the second conductivity type, and the second tunneling layer 532 of the second conductivity type positioned between the first tunneling layer 531 and the fourth semiconductor layer 180. The first tunneling layer 531 may be thinner than the fourth semiconductor layer 180 in the Z direction. The thickness of the first tunneling layer 531 may be about 20 nm or less in the Z direction. The second tunneling layer 532 may include a semiconductor material having a smaller energy band gap than the fourth semiconductor layer 180. As the first tunneling layer 531 contacts the second tunneling layer 532, the hole barrier height increases, so that holes may be injected into the second tunneling layer 532 through a tunneling phenomenon. As the second tunneling layer 532 and the fourth semiconductor layer 180 are bonded, a valence band VB notch is formed at the bonding surface of the second tunneling layer 532 and the fourth semiconductor layer 180, and holes accumulated in the notch may be injected into the fourth semiconductor layer 180 through a tunneling phenomenon. Accordingly, even if the fourth semiconductor layer 180 includes a p-type impurity and is made of a semiconductor material having a larger energy band gap than Si, and the work function of the material forming the anode electrode 210 is not larger than the work function of the material forming the fourth semiconductor layer 180, the anode electrode 210 and the fourth semiconductor layer 180 of the semiconductor device according to one or more embodiments may be in ohmic contact.

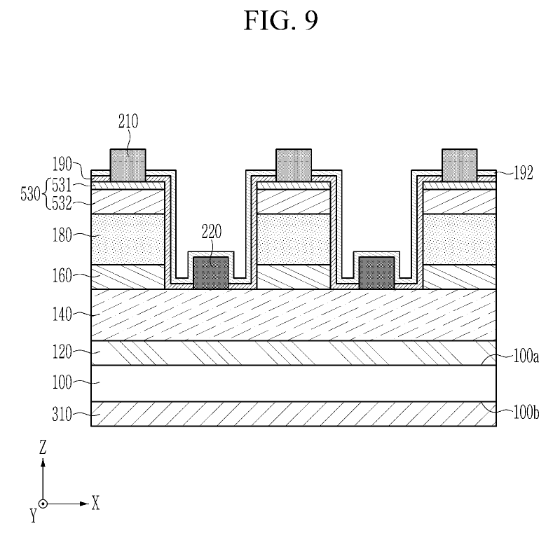

Hereinafter, a modified example of the semiconductor device will be described with reference to FIG. 9.

FIG. 9 is a cross-sectional view of a semiconductor device according to one or more embodiments. The embodiment illustrated in FIG. 9 may differ in some respects from the embodiment illustrated in FIG. 7 in that the gate electrode 220 contacts the second semiconductor layer 140. In the embodiment illustrated in FIG. 9, components that are the same as or have some different features from those illustrated in FIG. 7 may be referenced with the same drawing reference numerals. Description of aspects that are the same as or similar to those described above may be omitted.

Referring to FIG. 9, the gate electrode 220 of the semiconductor device according to one or more embodiments may be electrically connected to the second semiconductor layer 140. The gate electrode 220 may contact the second semiconductor layer 140. The lower surface of the gate electrode 220 may contact the upper surface of the second semiconductor layer 140.

In one or more embodiments, the semiconductor device may include a plurality of third semiconductor layers 160 spaced apart in the first direction (e.g., the X direction). The gate electrode 220 may be positioned between the plurality of third semiconductor layers 160 spaced apart in the first direction (e.g., the X direction) on the second semiconductor layer 140. The plurality of fourth semiconductor layers 180 spaced apart in the first direction (e.g., the X direction) may be respectively positioned on the plurality of third semiconductor layers 160 spaced apart in the first direction (e.g., the X direction). The gate electrode 220 may be positioned between the plurality of fourth semiconductor layers 180 spaced apart in the first direction (e.g., the X direction) on the second semiconductor layer 140. The gate electrode 220 may be spaced apart from the third semiconductor layer 160 and the fourth semiconductor layer 180. The side surface of the gate electrode 220 may be spaced apart from the side surface of the third semiconductor layer 160 and the side surface of the fourth semiconductor layer 180.

In one or more embodiments, the semiconductor device may include the plurality of gate electrodes 220 spaced apart in a first direction (e.g., the X direction). The plurality of gate electrodes 220 may be alternately arranged with the plurality of third semiconductor layers 160 in the first direction (e.g., the X direction).

In one or more embodiments, the first protective layer 190 may cover the upper surface of the second semiconductor layer 140. The first protective layer 190 may cover the side surface of the third semiconductor layer 160 and the side surface of the fourth semiconductor layer 180. The first protective layer 190 may cover the upper surface and side surfaces of the tunneling layer 530. The first protective layer 190 may cover the upper surface and side surface of the first tunneling layer 531 and the side surface of the second tunneling layer 532.

The gate electrode 220 may electrically connected to the second semiconductor layer 140 by the lower surface of the gate electrode 220 contacting the upper surface of the second semiconductor layer 140, but embodiments are not limited thereto. For example, the gate electrode 220 may contact the side surface or lower surface of the second semiconductor layer 140. The electrical connection structure of the gate electrode 220 and the second semiconductor layer 140 may be changed in various ways.

In various embodiments described above, the third semiconductor layer 160 and the fourth semiconductor layer 180 are provided as a single layer and may also be provided in plurality, such as that shown in FIG. 9 where a plurality of third semiconductor layers 160 and a plurality of fourth semiconductor layers 180 may be provided and be laterally spaced apart from each other. These constructions may also be referred to as, for example, a third semiconductor layer 160 partitioned into a plurality of portions that are laterally spaced apart from each other, and a fourth semiconductor layer 180 partitioned into a plurality of portions that are laterally spaced apart from each other.

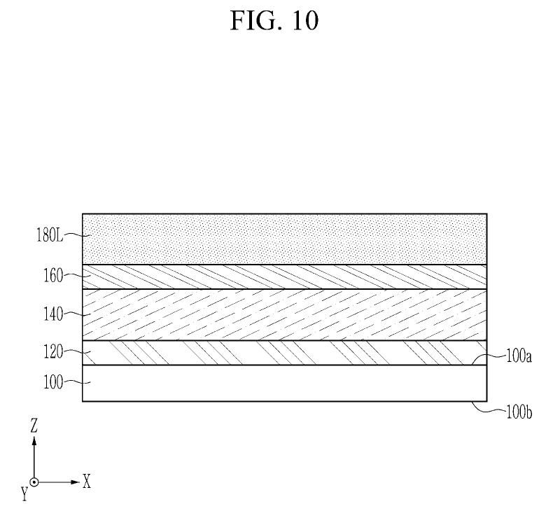

Hereinafter, a method for manufacturing a semiconductor device according to the embodiment of FIG. 1 will be described with reference to FIGS. 10-13.

FIGS. 10, 11, 12 and 13 are cross-sectional views illustrating a manufacturing process of a semiconductor device according to one or more embodiments.

Referring to FIG. 10, a first semiconductor layer 120, a second semiconductor layer 140, a third semiconductor layer 160, and a fourth semiconductor material layer 180L may be formed on a substrate b.

In one or more embodiments, the substrate 100 may be a semiconductor substrate including SiC. For example, the substrate 100 may be made of a 4H SiC substrate. In one or more embodiments, the substrate 100 may be made of a 3C SiC substrate, a 6H SiC substrate, etc. The substrate 100 may have a second conductivity type. The substrate 100 may be lightly doped with a second conductivity type. The second conductivity type may be, but is not limited to, n-type. The doping concentration of the substrate 100 may be about 1*10¹⁷cm⁻³ or more and about 5*10²⁰cm⁻³ or less. The resistivity of the substrate 100 may be about 0.005Ωcm or more and about 0.035Ωcm or less. The thickness of the substrate 100 may be about 10 µm or more and about 700 µm or less. The material, doping type, doping concentration, resistivity, thickness, etc. of the substrate 100 are not limited thereto and may be changed in various ways.

The substrate 100 may include a first surface 100a and a second surface 100b facing the first surface 100a. The first surface 100a of the substrate 100 may refer to the upper surface of the substrate 100, and the second surface 100b of the substrate 100 may refer to the lower surface of the substrate 100.

The first semiconductor layer 120, the second semiconductor layer 140, the third semiconductor layer 160, and the fourth semiconductor material layer 180L may be sequentially formed on the first surface 100a of the substrate 100. The first semiconductor layer 120, the second semiconductor layer 140, the third semiconductor layer 160, and the fourth semiconductor material layer 180L may be epitaxial layers formed from the substrate 100 through an epitaxial growth process. For example, the first semiconductor layer 120 may be formed on the first surface 100a of the substrate 100, the second semiconductor layer 140 may be formed on an upper surface of the first semiconductor layer 120, the third semiconductor layer 160 may be formed on an upper surface of the second semiconductor layer 140, and the fourth semiconductor layer 180 may be formed on an upper surface of the third semiconductor layer 160. The lower surface of the first semiconductor layer 120 may contact the first surface 100a of the substrate 100. The lower surface of the second semiconductor layer 140 may contact the upper surface of the first semiconductor layer 120. The lower surface of the third semiconductor layer 160 may contact the upper surface of the second semiconductor layer 140. The lower surface of the fourth semiconductor material layer 180L may contact the upper surface of the third semiconductor layer 160.

In one or more embodiments, the first semiconductor layer 120, the second semiconductor layer 140, the third semiconductor layer 160, and the fourth semiconductor material layer 180L may include SiC. For example, the first semiconductor layer 120, the second semiconductor layer 140, the third semiconductor layer 160, and the fourth semiconductor material layer 180L may include 4H SiC. The first semiconductor layer 120 and the third semiconductor layer 160 may be of the first conductivity type, and the second semiconductor layer 140 and the fourth semiconductor layer 180 may be of the second conductivity type. The first conductivity type may be n-type, and the second conductivity type may be p-type.

In one or more embodiments, the first semiconductor layer 120 may be heavily doped with the first conductivity type. The doping concentration of the first semiconductor layer 120 may be lower than the doping concentration of the substrate 100.

In one or more embodiments, the second semiconductor layer 140 may be lightly doped with the second conductivity type. The doping concentration of the second semiconductor layer 140 may be about 1*10¹⁴cm⁻³ or more and about 1*10¹⁷cm⁻³ or less. The thickness of the second semiconductor layer 140 may be about 1 µm or more and about 13 µm or less. The doping concentration, thickness, etc. of the second semiconductor layer 140 are not limited thereto and may be changed in various ways.

In one or more embodiments, the third semiconductor layer 160 may be lightly doped with the first conductivity type. The doping concentration of the third semiconductor layer 160 may be lower than the doping concentration of the first semiconductor layer 120. The doping concentration of the third semiconductor layer 160 may be about 1*10¹⁴cm⁻³ or more and about 1*10¹⁹cm⁻³ or less. The thickness of the third semiconductor layer 160 may be about 0.3 µm or more and about 1.1 µm or less. The doping concentration, thickness, etc. of the third semiconductor layer 160 are not limited thereto and may be changed in various ways.

In one or more embodiments, the fourth semiconductor material layer 180L may be heavily doped with the second conductivity type. The doping concentration of the fourth semiconductor material layer 180L may be higher than the doping concentration of the second semiconductor layer 140. The doping concentration of the fourth semiconductor material layer 180L may be about 1*10¹⁷cm⁻³ or more and about 5*10²⁰cm⁻³ or less. The doping concentration of the fourth semiconductor material layer 180L is not limited to this and may be changed in various ways.

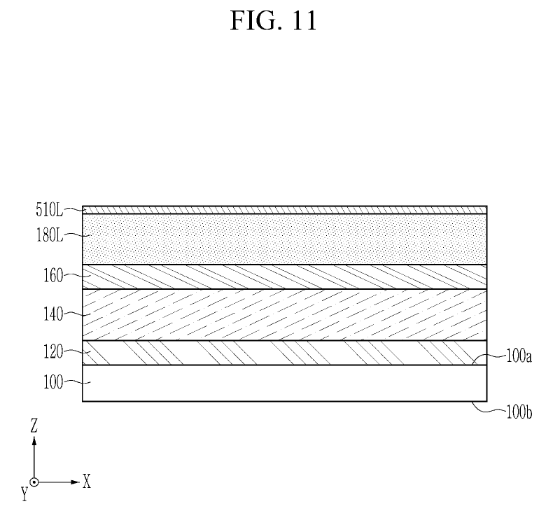

Referring to FIG. 11, a tunneling material layer 510L may be formed on the fourth semiconductor material layer 180L. The tunneling material layer 510L may be an epitaxial layer formed through an epitaxial growth process. The lower surface of the tunneling material layer 510L may contact the upper surface of the fourth semiconductor material layer 180L.

In one or more embodiments, the tunneling material layer 510L may include SiC. For example, the tunneling material layer 510L may include 4H SiC. The tunneling material layer 510L may be of the first conductivity type. The tunneling material layer 510L may be heavily doped with the first conductivity type. The first conductivity type may be n-type. In one or more embodiments, the doping concentration of the tunneling material layer 510L may be greater than or equal to about 1*10¹⁹cm⁻³ and less than or equal to about 5*10²¹cm⁻³. The doping concentration of the tunneling material layer 510L may be about 1*10²⁰cm⁻³ or more and about 1*10²¹cm⁻³ or less.

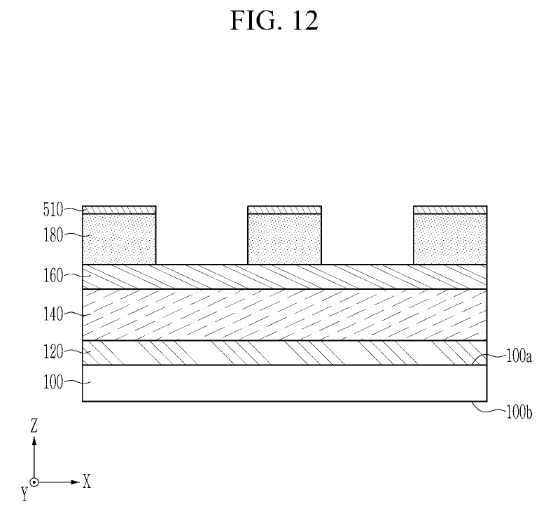

Referring to FIG. 12, the fourth semiconductor material layer 180L and the tunneling material layer 510L may be patterned. For example, a photoresist may be formed on a tunneling material layer 510L and a photoresist pattern may be formed through a photolithography process. The fourth semiconductor material layer 180L and the tunneling material layer 510L may be patterned by performing an etching process using a photoresist pattern. A portion of the fourth semiconductor material layer 180L and a portion of the tunneling material layer 510L may be etched to form a plurality of fourth semiconductor layers 180 (e.g., a plurality of portions of the fourth semiconductor layer 180 laterally spaced apart from each other) and a plurality of tunneling layers 510 (e.g., a plurality of portions of the tunneling layer 510 laterally spaced apart from each other). Afterwards, the photoresist pattern may be removed.

In one or more embodiments, the plurality of fourth semiconductor layers 180 may be spaced apart from each other in the first direction (e.g., the X direction) parallel to the upper surface of the third semiconductor layer 160 on the third semiconductor layer 160, and the plurality of tunneling layers 510 may be respectively positioned on the plurality of fourth semiconductor layers 180 spaced apart from each other in the first direction (e.g., the X direction).

The thickness of the tunneling layer 510 may be less than the thickness of the fourth semiconductor layer 180 in the Z direction. The thickness of the tunneling layer 510 may be less than the thickness of the third semiconductor layer 160 in the Z direction. The thickness of the tunneling layer 510 may be less than the thickness of the second semiconductor layer 140 in the Z direction. The thickness of the tunneling layer 510 may be less than the thickness of the first semiconductor layer 120 in the Z direction. In one or more embodiments, the thickness of the tunneling layer 510 may be less than or equal to about 20 nm in the Z direction.

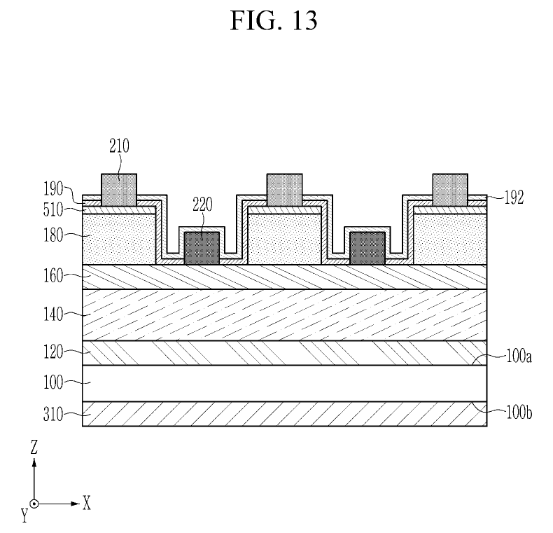

Referring to FIG. 13, an anode electrode 210 may be formed on the tunneling layer 510, and a gate electrode 220 may be formed on the third semiconductor layer 160. Additionally, a cathode electrode 310 may be formed on the second surface 100b of the substrate 100.

A first protective layer 190 may be formed on the third semiconductor layer 160, the fourth semiconductor layer 180, and the tunneling layer 510. The first protective layer 190 may be formed to cover the upper surface of the third semiconductor layer 160, the side surface of the fourth semiconductor layer 180, and the side surface and upper surface of the tunneling layer 510.

The first protective layer 190 may be patterned to form the gate electrode 220. For example, the first protective layer 190 may be patterned to form a first opening corresponding to the area where the gate electrode 220 is formed. At least a portion of the upper surface of the third semiconductor layer 160 may be exposed through the first opening. After depositing the gate electrode material layer, patterning may be performed to form the gate electrode 220 that fills the first opening. The gate electrode 220 may contact the upper surface of the third semiconductor layer 160.

A second protective layer 192 may be formed on the first protective layer 190 and the gate electrode 220. For example, the first protective layer 190 and the second protective layer 192 may be patterned to form a second opening corresponding to the area where the anode electrode 210 is formed. At least a portion of the upper surface of the tunneling layer 510 may be exposed by the second opening. After depositing the anode electrode material layer, patterning may be performed to form the anode electrode 210 that fills the second opening. The anode electrode 210 may contact the upper surface of the tunneling layer 510.

In one or more embodiments, the gate electrode 220 may be positioned between the plurality of fourth semiconductor layers 180 spaced apart in the first direction (e.g., the X direction). A plurality of gate electrodes 220 may be spaced apart from each other in the first direction (e.g., the X direction). The plurality of gate electrodes 220 may be alternately arranged with the plurality of fourth semiconductor layers 180 in the first direction (e.g., the X direction).

As described above, the gate electrode 220 may be formed first and the anode electrode 210 may be formed later, but embodiments are not limited thereto. For example, the anode electrode 210 may be formed first and the gate electrode 220 may be formed later.

The anode electrode 210 and the gate electrode 220 may include a conductive material. For example, each of the anode electrode 210 and the gate electrode 220 may include a metal, an alloy, a conductive metal nitride, a metal silicide, a doped semiconductor material, a conductive metal oxide, a conductive metal oxynitride, or a combination thereof. Each of the anode electrode 210 and the gate electrode 220 may include, but is not limited to, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. Each of the anode electrode 210 and the gate electrode 220 may be formed of a single layer or a plurality of layers.

In one or more embodiments, the anode electrode 210 and the gate electrode 220 may include different materials. However, embodiments are not limited thereto. For example, the anode electrode 210 and the gate electrode 220 may include the same material.

The first protective layer 190 and the second protective layer 192 may include an insulating material. For example, each of the first protective layer 190 and the second protective layer 192 may include, but is not limited to, silicon oxide, silicon phosphate, silicon nitride, silicon oxynitride, or a combination thereof.

The cathode electrode 310 may be formed on the second surface 100b of the substrate 100. The thickness of the substrate 100 may be reduced through a wafer thinning process before forming the cathode electrode 310. For example, a grinding process may be performed on the second surface 100b of the substrate 100. After reducing the thickness of the substrate 100 through a wafer thinning process, the cathode electrode 310 may be formed on the second surface 100b of the substrate 100. However, embodiments are not limited thereto. For example, the substrate 100 may be completely removed. In this case, the cathode electrode 310 may be formed on the lower surface of the first semiconductor layer 120. The lower surface of the first semiconductor layer 120 may mean the opposite surface of the upper surface of the first semiconductor layer 120 that contacts the second semiconductor layer 140.

The cathode electrode 310 may include a conductive material. For example, the cathode electrode 310 may include a metal, an alloy, a conductive metal nitride, a metal silicide, a doped semiconductor material, a conductive metal oxide, a conductive metal nitride, or a combination thereof. For example, the cathode electrode 310 may include, but is not limited to, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. In one or more embodiments, the cathode electrode 310 may include, but is not limited to, the same material as the anode electrode 210. The cathode electrode 310 may be formed of a single layer or a plurality of layers.

According to the embodiments illustrated in FIGS. 10-13, the tunneling layer 510 of FIG. 1 may be formed between the anode electrode 210 and the fourth semiconductor layer 180, but embodiments are not limited thereto.

For example, the tunneling layer 520 of FIG. 4 may be formed between the anode electrode 210 and the fourth semiconductor layer 180 using the same process. The tunneling layer 520 may include the first tunneling layer 521 and the second tunneling layer 522. In the process of FIG. 11, a first tunneling material layer of the second conductivity type and a second tunneling material layer of the second conductivity type may be formed. The second tunneling material layer may be formed on the fourth semiconductor material layer 180L, and the first tunneling material layer may be formed on the second tunneling material layer. In the process of FIG. 12, the first tunneling material layer, the second tunneling material layer, and the fourth semiconductor material layer 180L may be patterned to form the first tunneling layer 521, the second tunneling layer 522, and the fourth semiconductor layer 180. The first tunneling layer 521 may have a smaller energy band gap than the fourth semiconductor layer 180. The first tunneling layer 521 may have a smaller energy band gap than the second tunneling layer 522. The second tunneling layer 522 may have a higher doping concentration than the fourth semiconductor layer 180. The second tunneling layer 522 may have a higher doping concentration than the first tunneling layer 521.

The tunneling layer 530 of FIG. 7 may be formed between the anode electrode 210 and the fourth semiconductor layer 180 using the same process. The tunneling layer 530 may include the first tunneling layer 531 and the second tunneling layer 532. In the process of FIG. 11, a first tunneling material layer of the first conductivity type and a second tunneling material layer of the second conductivity type may be formed. The second tunneling material layer may be formed on the fourth semiconductor material layer 180L, and the first tunneling material layer may be formed on the second tunneling material layer. In the process of FIG. 12, the first tunneling material layer, the second tunneling material layer, and the fourth semiconductor material layer 180L may be patterned to form the first tunneling layer 531, the second tunneling layer 532, and the fourth semiconductor layer 180. The first tunneling layer 521 may be thinner than the fourth semiconductor layer 180. The thickness of the first tunneling layer 521 may be about 20 nm or less. The second tunneling layer 522 may have a smaller energy band gap than the fourth semiconductor layer 180. The second tunneling layer 522 may have a smaller energy band gap than the first tunneling layer 521.

According to an aspect of an example embodiment, a method for manufacturing a semiconductor device may include the steps of forming a first semiconductor layer of a first conductivity type, forming a second semiconductor layer of a second conductivity type on an upper surface of the first semiconductor layer, forming a third semiconductor layer of the first conductivity type on an upper surface of the second semiconductor layer, and forming a fourth semiconductor material layer of the second conductivity type on an upper surface of the third semiconductor layer, forming a tunneling material layer on an upper surface of the fourth semiconductor material layer, patterning the fourth semiconductor material layer and the tunneling material layer to form a plurality of fourth semiconductor layers and a plurality of tunneling layers spaced apart from each other in a first direction, forming a gate electrode electrically connected to the third semiconductor layer and positioned between the plurality of fourth semiconductor layers, and forming an anode electrode on each of the tunneling layers, and forming a cathode electrode on a lower surface of the first semiconductor layer.

The first conductivity type and the second conductivity type may be different.

The tunneling layer may be of the first conductivity type and may be thinner than the fourth semiconductor layer.

A thickness of the tunneling layer may be about 20 nm or less.

The tunneling layer may include a first tunneling layer between the anode electrode and the fourth semiconductor layer, and a second tunneling layer between the first tunneling layer and the fourth semiconductor layer.

The first tunneling layer may be of the first conductivity type, and the second tunneling layer may be of the second conductivity type.

The first tunneling layer may be thinner than the fourth semiconductor layer.

A thickness of the first tunneling layer may be about 20 nm or less.

An energy band gap of the second tunneling layer may be less than an energy band gap of the fourth semiconductor layer.

The fourth semiconductor layer and the second tunneling layer include Si and C, and the second tunneling layer may further include an element other than Si and C.

The fourth semiconductor layer and the second tunneling layer include Si and C, and a Si content (at%) of the second tunneling layer may be higher than a Si content (at%) of the fourth semiconductor layer.

The fourth semiconductor layer and the second tunneling layer include Ga and N, and the second tunneling layer may further include an element other than Ga and N.

The energy band gap of the second tunneling layer may be less than an energy band gap of the first tunneling layer.

The first tunneling layer and the second tunneling layer may be of the second conductivity type.

An energy band gap of the first tunneling layer may be less than the energy band gap of the second tunneling layer.

The energy band gap of the first tunneling layer may be less than an energy band gap of the fourth semiconductor layer.

A doping concentration of the second tunneling layer may be higher than a doping concentration of the first tunneling layer.

The doping concentration of the second tunneling layer may be higher than a doping concentration of the fourth semiconductor layer.

According to embodiments, an ohmic contact between a p-type semiconductor layer and an electrode of a semiconductor device using a semiconductor material having a high energy band gap may be provided.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a cathode electrode,
a first semiconductor layer of a first conductivity type, a second semiconductor layer of a second conductivity type, a third semiconductor layer of the first conductivity type, and at least one fourth semiconductor layer of the second conductivity type that are sequentially stacked on the cathode electrode in a first direction,
a gate electrode connected to the second semiconductor layer or the third semiconductor layer,
an anode electrode on the at least one fourth semiconductor layer, and
a first tunneling layer of the first conductivity type between the anode electrode and the at least one fourth semiconductor layer,
wherein the second conductivity type is different from the first conductivity type, and
wherein, in the first direction, a thickness of the first tunneling layer is less than a thickness of the at least one fourth semiconductor layer.

2. The semiconductor device of claim 1, wherein a doping concentration of the first tunneling layer is higher than a doping concentration of the first semiconductor layer and higher than a doping concentration of the third semiconductor layer.

3. The semiconductor device of claim 1, further comprising a second tunneling layer between the first tunneling layer and the at least one fourth semiconductor layer,
wherein the second tunneling layer is of the second conductivity type, and
wherein an energy band gap of the second tunneling layer is less than an energy band gap of the at least one fourth semiconductor layer.

4. The semiconductor device of claim 3, wherein:
both the at least one fourth semiconductor layer and the second tunneling layer comprise SiC, and the second tunneling layer further comprises an element other than Si and C, or
both the at least one fourth semiconductor layer and the second tunneling layer comprise GaN, and the second tunneling layer further comprises an element other than Ga and N.

5. The semiconductor device of claim 3, wherein the at least one fourth semiconductor layer and the second tunneling layer comprise SiC, and
wherein an Si content of the second tunneling layer is higher Si than an Si content of the at least one fourth semiconductor layer.

6. The semiconductor device of claim 3, wherein the energy band gap of the second tunneling layer is less than an energy band gap of the first tunneling layer.

7. The semiconductor device of claim 1, wherein the at least one fourth semiconductor layer comprises a plurality of fourth semiconductor layers spaced apart in a second direction perpendicular to the first direction, and
wherein the gate electrode is between the plurality of fourth semiconductor layers.

8. The semiconductor device of claim 7, wherein, in the first direction, a lower surface of the gate electrode contacts an upper surface of the third semiconductor layer, and
wherein, in the second direction, a side surface of the gate electrode is spaced apart from a side surface of at least one of the plurality of fourth semiconductor layers.

9. The semiconductor device of claim 1, wherein the first conductivity type is n-type and the second conductivity type is p-type.

10. A semiconductor device comprising:
a cathode electrode,
a first semiconductor layer of a first conductivity type, a second semiconductor layer of a second conductivity type, a third semiconductor layer of the first conductivity type, and a fourth semiconductor layer of the second conductivity type that are sequentially stacked on the cathode electrode in a first direction,
a gate electrode connected to the second semiconductor layer or the third semiconductor layer,
an anode electrode on the fourth semiconductor layer,
a first tunneling layer between the anode electrode and the fourth semiconductor layer, and
a second tunneling layer between the first tunneling layer and the fourth semiconductor layer,
wherein the second conductivity type is different from the first conductivity type, and
wherein an energy band gap of the first tunneling layer is different from an energy band gap of the second tunneling layer.

11. The semiconductor device of claim 10, wherein the first tunneling layer and the second tunneling layer are of the second conductivity type.

12. The semiconductor device of claim 11, wherein the energy band gap of the first tunneling layer is less than the energy band gap of the second tunneling layer.

13. The semiconductor device of claim 12, wherein a doping concentration of the second tunneling layer is higher than a doping concentration of the first tunneling layer.

14. The semiconductor device of claim 13, wherein the doping concentration of the second tunneling layer is higher than a doping concentration of the fourth semiconductor layer.

15. The semiconductor device of claim 10, wherein the first tunneling layer is of the first conductivity type and the second tunneling layer is of the second conductivity type.

16. The semiconductor device of claim 15, wherein, in the first direction, a thickness of the first tunneling layer is less than a thickness of the fourth semiconductor layer.

17. The semiconductor device of claim 16, wherein a doping concentration of the first tunneling layer is higher than a doping concentration of the first semiconductor layer and higher than a doping concentration of the third semiconductor layer.

18. The semiconductor device of claim 16, wherein the energy band gap of the second tunneling layer is less than an energy band gap of the fourth semiconductor layer.

19. The semiconductor device of claim 18, wherein the energy band gap of the second tunneling layer is less than the energy band gap of the first tunneling layer.

20. A semiconductor device comprising:
a cathode electrode,
a first semiconductor layer of a first conductivity type, a second semiconductor layer of a second conductivity type, a third semiconductor layer of the first conductivity type, and a fourth semiconductor layer of the second conductivity type that are sequentially stacked on the cathode electrode,
a gate electrode connected to the second semiconductor layer or the third semiconductor layer,
an anode electrode on the fourth semiconductor layer, and
a first tunneling layer between the anode electrode and the fourth semiconductor layer,
wherein the first tunneling layer is of the second conductivity type,
wherein the second conductivity type is different from the first conductivity type, and
wherein an energy band gap of the first tunneling layer is less than an energy band gap of the fourth semiconductor layer.
